(19) United States
(12) Patent Application Publication
(10) Pub. No.: US 2023/0114051 A1
(43) Pub. Date: Apr. 13, 2023

(54) DISPLAY SUBSTRATE, METHOD FOR MANUFACTURING THE SAME, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Mengmeng DU, Beijing (CN); Bo CHENG, Beijing (CN); Yixiang YANG, Beijing (CN); Biao LIU, Beijing (CN); Xiaoqing SHU, Beijing (CN); Jie GOU, Beijing (CN); Zhenhua ZHANG, Beijing (CN)

(21) Appl. No.: 17/909,530

(22) PCT Filed: Aug. 16, 2021
(86) PCT No.: PCT/CN2021/112669

§ 371 Date: Sep. 6, 2022

(30) Foreign Application Priority Data
Sep. 30, 2020 (CN) 202011057139.1

(51) Int. Cl. H10K 59/124; H10K 71/00

(52) U.S. Cl. CPC H01L 27/3258; H01L 51/56; H01L 2227/323

(57) ABSTRACT

A display substrate, a method for manufacturing the same, and a display device are provided. The display substrate includes a base substrate, and a drive circuit layer disposed on the base substrate, the display substrate having an active area and a fan-out area, the drive circuit layer being provided with a crack-stopping groove therein, the crack-stopping groove being located between the active area and the fan-out area. According to the embodiments of the present disclosure, with the crack-stopping groove provided between the active area and the fan-out area, in the case where a crack occurs in a structure in the active area of the display substrate, the crack is prevented from extending to the fan-out area by isolation of the crack-stopping groove, thereby reducing the possibility of structures in the fan-out area of the display panel being damaged and improving the reliability of the display panel.

### CROSS-REFERENCE TO RELATED APPLICATIONS

This application claims priority to Chinese Patent Application No. 202011057139.1 filed in China on Sep. 30, 2020, the entire contents of which are hereby incorporated by reference.

### TECHNICAL FIELD

The present disclosure relates to the technical field of display, and more particularly, to a display substrate, a method for manufacturing the same, and a display device.

### BACKGROUND

With the development of display technology, the technology of Organic Light-Emitting Diode (OLED) display panels is becoming more and more perfect. In the related art, the screen ratio of a display device is generally improved based on the Pading-Bending technology, which refers to bending a fan-out area at the position where pixel lines are connected to external circuitry to the back of the display panel to connect to a bonding structure. However, due to the limitation of material, the structures in the display substrate, such as the base substrate, may be cracked during bending of the display panel, thereby affecting the performance of the display panel.

### SUMMARY

Embodiments of the present disclosure provide a display substrate, a method for manufacturing the same, and a display device to solve the problem that the structures may be cracked during bending of the display panel.

In a first aspect, an embodiment of the present disclosure provides a display substrate, including a base substrate, and a drive circuit layer disposed on the base substrate, the display substrate having an active area and a fan-out area, the drive circuit layer being provided with a crack-stopping groove therein, the crack-stopping groove being located between the active area and the fan-out area.

In some embodiments, the drive circuit layer includes an insulating layer, a signal line, a protective layer and a planarization layer which are laminated in sequence in a direction away from the base substrate, and at least part of the crack-stopping groove is located in the planarization layer.

In some embodiments, the crack-stopping groove penetrates the planarization layer in a direction perpendicular to the base substrate.

In some embodiments, the planarization layer includes a first planarization sub-layer and a second planarization sub-layer which are laminated in sequence in a direction away from the base substrate, and the crack-stopping groove penetrates the first planarization sub-layer and the second planarization sub-layer in a direction perpendicular to the base substrate.

In some embodiments, at least a part of the crack-stopping groove is located in the protective layer.

In some embodiments, in the direction perpendicular to the base substrate, the depth of the part of the crack-stopping groove in the protective layer is less than the thickness of the protective layer.

In some embodiments, in the direction perpendicular to the base substrate, the depth of the part of the crack-stopping groove in the planarization layer is less than the thickness of the planarization layer.

In some embodiments, the planarization layer includes a first planarization sub-layer and a second planarization sub-layer which are laminated in sequence in a direction away from the base substrate, and the crack-stopping groove penetrates the second planarization sub-layer in a direction perpendicular to the base substrate.

In some embodiments, in the direction perpendicular to the base substrate, the depth of the part of the crack-stopping groove in the planarization layer is equal to the thickness of the second planarization sub-layer.

In some embodiments, in the direction perpendicular to the base substrate, the depth of the part of the crack-stopping groove in the planarization layer is greater than the thickness of the second planarization sub-layer.

In some embodiments, in a direction parallel to the base substrate, the crack-stopping groove extends in a direction parallel to an interface between the active area and the fan-out area.

In a second aspect, an embodiment of the present disclosure provides a display device including the display substrate of any one of the first aspect.

In a third aspect, an embodiment of the present disclosure provides a method for manufacturing a display substrate, including:

providing a base substrate;

manufacturing a drive circuit layer on the base substrate; and

forming a crack-stopping groove in the drive circuit layer, where the display substrate has an active area and a fan-out area, and the crack-stopping groove is located between the active area and the fan-out area.

According to the embodiments of the present disclosure, with the crack-stopping groove provided between the active area and the fan-out area, in the case where a crack occurs in a structure in the active area of the display substrate, the crack is prevented from extending to the fan-out area by isolation of the crack-stopping groove, thereby reducing the possibility of structures in the fan-out area of the display panel being damaged and improving the reliability of the display panel.

### BRIEF DESCRIPTION OF THE DRAWINGS

In order to more clearly illustrate the technical solutions of the embodiments of the present disclosure, a brief description will be given below with reference to the accompanying drawings which are required to be used in the description of the embodiments of the present disclosure; it is obvious that the drawings in the following description are only some embodiments of the present disclosure, and it would have been obvious for a person of ordinary skill in the art to obtain other drawings according to these drawings without involving any inventive effort.

FIG. 1 is a block diagram of a display substrate in accordance with an embodiment of the present disclosure;

FIG. 2 is a flowchart of a method for manufacturing a display substrate in accordance with an embodiment of the present disclosure;

FIG. 3 is another block diagram of a display substrate in accordance with an embodiment of the present disclosure;

FIG. 4 is another block diagram of a display substrate in accordance with an embodiment of the present disclosure;

FIG. 5 is another block diagram of a display substrate in accordance with an embodiment of the present disclosure; and

FIG. 6 is yet still another block diagram of a display substrate in accordance with an embodiment of the present disclosure.

### DETAILED DESCRIPTION

The embodiments of the present disclosure will now be described more fully hereinafter with reference to the accompanying drawings, in which some, but not all embodiments of the disclosure are shown. Based on the embodiments in the present disclosure, all other embodiments obtained by a person of ordinary skill in the art without inventive effort fall within the scope of the present disclosure.

The present disclosure provides a display substrate.

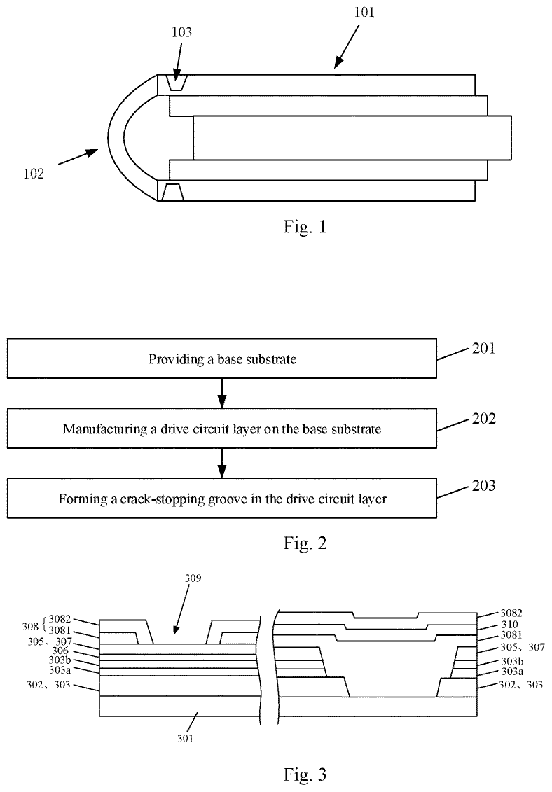

As shown in FIG. 1, in an embodiment, the display substrate includes a base substrate, and a drive circuit layer disposed on the base substrate.

The technical solution of this embodiment can be applied to an OLED display substrate, in particular a display substrate designed based on Pad bending.

The display substrate designed based on Pad bending has an active area (AA) 101 and a fan-out area (Fanout) 102, and various signal lines led out of the display substrate are bent to the back of the display substrate in the fan-out area 102 so as to realize a narrow bezel design and improve the screen ratio of the display substrate and a display panel using the display substrate.

In the process of implementing the technical solution of the present application, the inventor of the present application has found that the fan-out area 102 of the display substrate has a minimum bending radius due to the limitation of the materials of the substrate and the like of the display substrate. Obviously, the smaller the bending radius is, the smaller the frame size of the display substrate is, but a certain mechanical unreliability may be caused, for example, a crack may be generated due to local stress concentration, and the crack may further extend and transfer. If the crack extends to the fan-out area 102, the connection effect may be affected, so that the display panel has an abnormal display state such as a bright line.

Still referring to FIG. 1, in the embodiment of the present disclosure, a crack-stopping groove 103 is further formed in the drive circuit layer and is located between the active area 101 and the fan-out area 102.

By providing the crack-stopping groove 103, when the structure on the drive circuit layer generates a crack and extends to the crack-stopping groove 103, the stress can be released due to the existence of the crack-stopping groove 103, so that the crack cannot pass through the crack-stopping groove 103 and extend to the fan-out area 102, ensuring the structural integrity and reliability of the fan-out area 102. In practice, the frame size of the display substrate can be further appropriately reduced, thereby further improving the screen ratio of the display substrate.

Thus, according to the embodiments of the present disclosure, with the crack-stopping groove 103 provided between the active area 101 and the fan-out area 102, in the case where a crack occurs in a structure in the active area 101 of the display substrate, the crack is prevented from extending to the fan-out area 102 by isolation of the crack-stopping groove 103, thereby reducing the possibility of structures in the fan-out area 102 of the display panel being damaged and improving the reliability of the display panel.

An embodiment of the present disclosure further provides a method for manufacturing a display substrate.

In an embodiment, the method for manufacturing a display substrate includes the following steps:

at step 201: a base substrate is provided;

at step 202: a drive circuit layer is manufactured on the base substrate; and

at step 203: a crack-stopping groove is formed in the drive circuit layer, where the display substrate has an active area and a fan-out area, and the crack-stopping groove is located between the active area and the fan-out area.

In the technical solution of this embodiment, the base substrate and the step of manufacturing the drive circuit layer can refer to the related art to a certain extent, and furthermore, a crack-stopping groove is formed in the drive circuit layer.

It should be understood that the above-mentioned step 203 may be specifically performed after the drive circuit layer is completely fabricated, or may be inserted in the process of manufacturing the drive circuit layer, for example, first manufacturing part of the structures of the drive circuit layer, then forming a crack-stopping groove in the fabricated structure, and further continuing to fabricate other structures of the drive circuit layer.

Since this embodiment can produce the display substrate in the above-mentioned display substrate embodiment, at least substantially the same or similar technical effects can be achieved, which will not be described in detail herein. In some embodiments, the crack-stopping groove penetrates the planarization layer in a direction perpendicular to the base substrate.

In some embodiments, the drive circuit layer includes an insulating layer, a signal line, a protective layer and a planarization layer which are laminated in sequence in a direction away from the base substrate, and at least part of the crack-stopping groove is located in the planarization layer.

In the technical solution of this embodiment, at least part of the crack-stopping groove is located in the planarization layer, that is to say, it is possible that the crack-stopping groove is only formed at the planarization layer, and it is also possible that a part of the crack-stopping groove extends to other structures, for example to the above-mentioned protective layer.

As shown in FIG. 3, in this embodiment, in the manufacturing process, the fabrication of the previous film layers, such as a barrier layer 302 and a buffer layer 303, a gate metal layer (not shown), gate insulation layers 304a and 304b, a source and drain metal layer, an insulating layer 305, a signal line 306 and a protective layer 307, is firstly completed on the base substrate 301, where the protective layer 306 is used for protecting the signal line 306, the insulating layer 305 is used for providing an insulation environment for the signal line 306, and the material of the protective layer 306 is generally selected from inorganic materials.

After the fabrication of the protective layer 306 is completed, a planarization layer 308 is further fabricated.

In the process of manufacturing the planarization layer 308, the material of the planarization layer 308 is first deposited, and then the patterning of the planarization layer 308 is accomplished by processes such as exposure, curing, desmearing, etc.

In patterning the planarization layer 308, a region corresponding to the crack-stopping groove 309 is removed to form the crack-stopping groove 309.

In some embodiments, the planarization layer 308 includes a first planarization sub-layer 3081 and a second planarization sub-layer 3082 which are laminated in sequence in a direction away from the base substrate 301, and the crack-stopping groove 309 penetrates the first planarization sub-layer 3081 and the second planarization sub-layer 3082 in a direction perpendicular to the base substrate 301.

In this embodiment, the first planarization sub-layer 3081 and the second planarization sub-layer 3082 are laminated, and further, the source/drain metal layer of the display substrate includes a first source/drain electrode sub-layer (not shown) and a second source/drain electrode sub-layer 310, where the first source/drain electrode sub-layer is fabricated before the first planarization sub-layer.

In the embodiment of the present disclosure, during the fabrication of the first planarization sub-layer 3081, a plasma glue residue removal process can be further selected for fabrication. It should be understood that the planarization layer 308 generally uses an organic material, and the adhesion between the organic material and an inorganic material or a metal material is relatively poor, therefore, a plasma glue residue removal process is used in the embodiment to improve the connection effect between the first planarization sub-layer 3081 and the second source/drain electrode sub-layer 310.

After the fabrication of the first planarization sub-layer 3081 is completed, the fabrication of the second source/drain electrode sub-layer 310 is completed on the side of the first planarization sub-layer 3081 remote from the base substrate 301 by exposure, development, etching, lift-off processes, etc.

After the second source/drain sub-layer 310 is fabricated, a second planarization sub-layer 3082 is further fabricated on the side surface of the second source/drain sub-layer 310 remote from the base substrate 301.

The fabrication process of the second planarization sub-layer 3082 may refer to the first planarization sub-layer 3081, which will not be described again, and after the second planarization sub-layer 3082 is fabricated, further fabrication of a light emitting unit (not shown) may be performed.

Generally, a light-emitting unit includes a first electrode, a light-emitting layer and a second electrode which are arranged in a stack, and in practice, the fabrication of the first electrode can be accomplished by a process such as deposition, exposure, development, wet etching, ashing, stripping and the like.

Since the second planarization sub-layer 3082 may also employ a plasma desmearing process, the bonding effect between the second planarization sub-layer 3082 and the first electrode may be improved.

In some embodiments, at least a part of the crack-stopping groove is located in the protective layer.

It should be appreciated that in forming the pattern of the first planarization sub-layer by a desmearing process, the material of the region corresponding to the crack-stopping groove may be removed, which, due to limitations of the process and the like, may result in a part of the protective layer also being removed such that a part of the crack-stopping groove is formed in the protective layer.

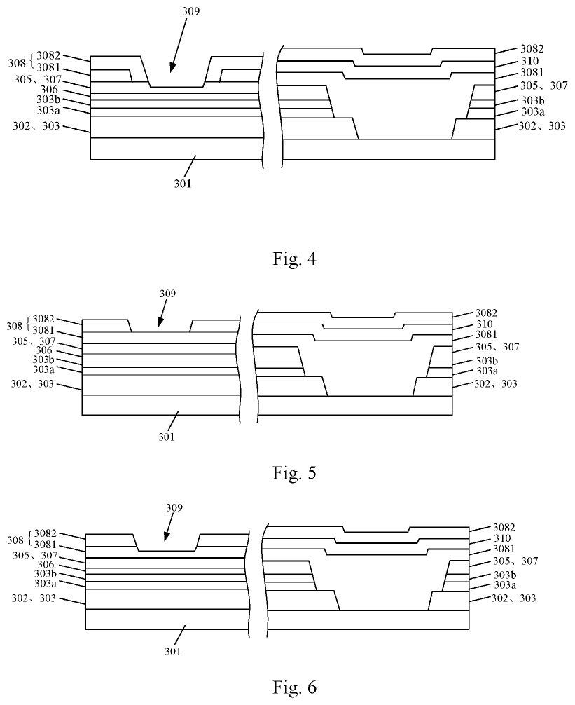

As shown in FIG. 4, the crack-stopping groove 309 in the protective layer 307 is formed simultaneously when the crack-stopping groove 309 is formed in the material of the first planarization sub-layer 3081 during the fabrication.

Still referring to FIG. 4, in some embodiments, in the direction perpendicular to the base substrate 301, the depth of the portion of the crack-stopping groove 309 in the protective layer 307 is less than the thickness of the protective layer 307.

In this embodiment, the depth of the part of the crack-stopping groove 309 in the protective layer 307 should be as small as possible to avoid affecting the protective effect of the protective layer 307 on other structures such as the signal line 306 located between the protective layer 307 and the base substrate 301.

As shown in FIGS. 4 and 5, in some embodiments, in the direction perpendicular to the base substrate 301, the depth of the portion of the crack-stopping groove 309 in the planarization layer 308 is less than the thickness of the planarization layer 308.

In the technical solution of this embodiment, in order to reduce the possible adverse effect on the protective layer 307 and other structures, in the direction perpendicular to the substrate 301, the depth of the crack-stopping groove 309 is further controlled to be less than the thickness of the planarization layer 308.

In other words, in the technical solution of this embodiment, the crack-stopping groove 309 extends only to a part of the planarization layer 308 and does not extend through the planarization layer 308, thereby reducing the adverse effect that may be caused to other structures such as the protective layer 307 during the fabrication of the crack-stopping groove 309.

As shown in FIGS. 4 and 5, in some embodiments, the planarization layer 308 includes a first planarization sub-layer 3081 and a second planarization sub-layer 3082 which are laminated in sequence in a direction away from the base substrate 301, and the crack-stopping groove 309 penetrates the second planarization sub-layer 3082 in a direction perpendicular to the base substrate.

Different from the embodiment shown in FIGS. 3 and 4, in the technical solution of this embodiment, the crack-stopping groove 309 only penetrates the second planarization sub-layer 3082, but does not penetrate the first planarization sub-layer 3081.

In the fabrication process, the fabrication of a part of structures of the drive circuit layer, such as the first source/drain metal sub-layer (not shown), the insulating layer 305, the signal line 306, the protective layer 307, etc. is first completed on the base substrate 301.

Next, the first planarization sub-layer 3081 is formed on the protective layer 307. The process for forming the first planarization sub-layer 3081 may refer to the embodiments shown in FIGS. 3 and 4.

The main difference from the embodiment shown in FIGS. 3 and 4 is that in this embodiment, the material of the region of the first planarization sub-layer 3081 corresponding to the crack-stopping groove 309 is not removed.

After fabrication of the first planarization sub-layer 3081 is completed, a second source/drain metal sub-layer 310 and a second planarization sub-layer 3082 are further fabricated on the first planarization sub-layer 3081.

The steps of manufacturing the second source/drain metal sub-layer 310 and the second planarization sub-layer 3082 may refer to the embodiments shown in FIGS. 3 and 4.

In manufacturing the second planarization sub-layer 3082, a region of the second planarization layer 3082 corresponding to the crack to the crack-stopping groove 309 is removed by a plasma desmearing process to form the crack-stopping groove 309.

In some embodiments, as shown in FIG. 5, in the direction perpendicular to the base substrate 301, the depth of the part of the crack-stopping groove 309 in the planarization layer 308 is equal to the thickness of the second planarization sub-layer 3082. That is, the crack-stopping groove 103 is formed only in the second planarization sub-layer 3082.

In other embodiments, as shown in FIG. 6, in the direction perpendicular to the base substrate 301, the depth of the part of the crack-stopping groove 309 in the planarization layer 308 is greater than the thickness of the second planarization sub-layer 3082.

As shown in FIG. 6, in this embodiment, when the plasma desmearing process removes the material of the region of the second planarization sub-layer 3082 corresponding to the crack-stopping groove 309, and a part of the material of the first planarization sub-layer 3081 is also removed due to process and other factors. As such, the crack-stopping groove 309 is formed through the second planarization sub-layer 3082 and extends partially to the first planarization sub-layer 3081 so as to avoid affecting other results such as the protective layer 307.

In some embodiments, in a direction parallel to the base substrate, the crack-stopping groove extends in a direction parallel to an interface between the active area and the fan-out area. By controlling the crack-stopping grooves to extend in a direction parallel to the interface between the active area and the fan-out area, it is possible to further reduce the possibility that cracks generated in the active area extend to the fan-out area, which contributes to improving the reliability of the display panel.

An embodiment of the present disclosure provides a display device including the display substrate of any one of the first aspect.

Since this embodiment includes all the technical solutions of the above-mentioned display substrate embodiments, at least all the above-mentioned technical effects can be achieved, and the description thereof will not be repeated here.

According to the embodiments of the present disclosure, with the crack-stopping groove 103 provided between the active area 101 and the fan-out area 102, in the case where a crack occurs in a structure in the active area 101 of the display substrate, the crack is prevented from extending to the fan-out area 102 by isolation of the crack-stopping groove 103, thereby reducing the possibility of structures in the fan-out area 102 of the display panel being damaged and improving the reliability of the display panel.

While the present disclosure has been described with reference to specific embodiments thereof, it will be understood by those skilled in the art that various changes may be made and equivalents may be substituted for elements thereof without departing from the scope of the disclosure. Accordingly, the protection sought herein is as set forth in the claims below.

1. A display substrate, comprising a base substrate, and a drive circuit layer disposed on the base substrate, the display substrate comprising an active area and a fan-out area, the drive circuit layer being provided with a crack-stopping groove, the crack-stopping groove being located between the active area and the fan-out area.

2. The display substrate according to claim 1, wherein the drive circuit layer comprises an insulating layer, a signal line, a protective layer and a planarization layer which are laminated in sequence in a direction away from the base substrate, and at least part of the crack-stopping groove is located in the planarization layer.

3. The display substrate according to claim 2, wherein the crack-stopping groove penetrates the planarization layer in a direction perpendicular to the base substrate.

4. The display substrate according to claim 3, wherein the planarization layer comprises a first planarization sub-layer and a second planarization sub-layer which are laminated in sequence in a direction away from the base substrate, and the crack-stopping groove penetrates the first planarization sub-layer and the second planarization sub-layer in a direction perpendicular to the base substrate.

5. The display substrate according to claim 3, wherein at least a part of the crack-stopping groove is located in the protective layer.

6. The display substrate according to claim 5, wherein in the direction perpendicular to the base substrate, the depth of the part of the crack-stopping groove in the protective layer is less than the thickness of the protective layer.

7. The display substrate according to claim 2, wherein in the direction perpendicular to the base substrate, the depth of the part of the crack-stopping groove in the planarization layer is less than the thickness of the planarization layer.

8. The display substrate according to claim 7, wherein the planarization layer comprises a first planarization sub-layer and a second planarization sub-layer which are laminated in sequence in a direction away from the base substrate, and the crack-stopping groove penetrates the second planarization sub-layer in a direction perpendicular to the base substrate.

9. The display substrate according to claim 8, wherein in the direction perpendicular to the base substrate, the depth of the part of the crack-stopping groove in the planarization layer is equal to the thickness of the second planarization sub-layer.

10. The display substrate according to claim 8, wherein in the direction perpendicular to the base substrate, the depth of the part of the crack-stopping groove in the planarization layer is greater than the thickness of the second planarization sub-layer.

11. The display substrate according to claim 1, wherein in a direction parallel to the base substrate, the crack-stopping groove extends in a direction parallel to an interface between the active area and the fan-out area.

12. A display device comprising the display substrate of claim 1.

13. A method for manufacturing a display substrate, comprising:
providing a base substrate;
manufacturing a drive circuit layer on the base substrate; and
forming a crack-stopping groove in the drive circuit layer, wherein the display substrate has an active area and a fan-out area, and the crack-stopping groove is located between the active area and the fan-out area.
